(19) United States
(12) Patent Application Publication
(10) Pub. No.: US 2022/0112603 A1
(43) Pub. Date: Apr. 14, 2022

(54) SUBSTRATE PROCESSING METHOD AND SUBSTRATE PROCESSING APPARATUS

(71) Applicant: Tokyo Electron Limited, Tokyo (JP)

(72) Inventors: Hiroki SAKURAI, Kumamoto (JP); Daisuke GOTO, Kumamoto (JP); Nobuhiro OGATA, Kumamoto (JP); Yusuke HASHIMOTO, Kumamoto (JP); Shoki MIZUGUCHI, Kumamoto (JP); Yenrui HSU, Kumamoto (JP)

(73) Assignee: Tokyo Electron Limited, Tokyo (JP)

(21) Appl. No.: 17/495,837

(22) Filed: Oct. 7, 2021

(30) Foreign Application Priority Data
Oct. 9, 2020 (JP) 2020 171409
Sep. 15, 2021 (JP) 2021 149973

(51) Int. Cl. C23C 18/18; C23C 18/16

(52) U.S. Cl. CPC C23C 18/1824; C23C 18/1657; C23C 18/168

(57) ABSTRACT

A substrate processing method includes discharging a processing liquid to a substrate, and discharging a mixed fluid that is produced by mixing a processing liquid and a purified water in a vapor state or a mist state thereof to a substrate where a processing liquid is discharged.

### CROSS-REFERENCE TO RELATED APPLICATIONS

The present application claims the benefit of priority to Japanese Patent Application No. 2020-171409 filed on Oct. 9, 2020, the entire contents of which Japanese Patent Application are incorporated by reference in the present application, and Japanese Patent Application No. 2021-149973 filed on Sep. 15, 2021, the entire contents of which Japanese Patent Application are incorporated by reference in the present application.

### FIELD

A disclosed embodiment(s) relate(s) to a substrate processing method and a substrate processing apparatus.

### BACKGROUND

A technique to remove a resist film that is formed on a substrate such as a semiconductor wafer (that will also be referred to as a wafer below) in an SPM (Sulfuric Acid Hydrogen Peroxide Mixture) process has conventionally been known. Such an SPM process is executed by supplying an SPM liquid that is produced by mixing sulfuric acid and a hydrogen peroxide solution to a resist film on a substrate (see Japanese Patent Application Publication No. 2014-027245).

### SUMMARY

A substrate processing method according to an aspect of the present disclosure includes a processing liquid discharge step, and a mixed fluid discharge step. The processing liquid discharge step discharges a processing liquid to a substrate. The mixed fluid discharge step discharges a mixed fluid that is produced by mixing the processing liquid and a purified water in a vapor state or a mist state thereof to the substrate where the processing liquid is discharged.

### BRIEF DESCRIPTION OF DRAWING(S)

FIG. 1 is a schematic diagram that illustrates a general configuration of a substrate processing system according to an embodiment.

FIG. 2 is a schematic diagram that illustrates a configuration example of a processing unit according to an embodiment.

FIG. 3 is a cross-sectional view that illustrates a configuration example of a nozzle according to an embodiment.

FIG. 4 is a schematic diagram that illustrates a step of substrate processing according to an embodiment.

FIG. 5 is a schematic diagram that illustrates a step of substrate processing according to an embodiment.

FIG. 6 is a schematic diagram that illustrates a step of substrate processing according to an embodiment.

FIG. 7 is a schematic diagram that illustrates a step of substrate processing according to an embodiment.

FIG. 8 is a schematic diagram that illustrates a step of substrate processing according to an embodiment.

FIG. 9 is a schematic diagram that illustrates a step of substrate processing according to an embodiment.

FIG. 10 is a schematic diagram that illustrates a configuration example of a processing unit according to variation 1 of an embodiment.

FIG. 11 is a schematic diagram that illustrates a configuration example of a processing unit according to variation 2 of an embodiment.

FIG. 12 is a schematic diagram that illustrates a step of substrate processing according to variation 2 of an embodiment.

FIG. 13 is a schematic diagram that illustrates a step of substrate processing according to variation 2 of an embodiment.

FIG. 14 is a schematic diagram that illustrates a step of substrate processing according to variation 3 of an embodiment.

FIG. 15 is a schematic diagram that illustrates a step of substrate processing according to variation 3 of an embodiment.

FIG. 16 is a flowchart that illustrates a procedure of substrate processing that is executed by a substrate processing system according to an embodiment.

FIG. 17 is a flowchart that illustrates a procedure of substrate processing that is executed by a substrate processing system according to variation 1 of an embodiment.

FIG. 18 is a flowchart that illustrates a procedure of substrate processing that is executed by a substrate processing system according to variation 2 of an embodiment.

### DESCRIPTION OF EMBODIMENT(S)

Hereinafter, an embodiment(s) of a substrate processing method and a substrate processing apparatus as disclosed in the present application will be explained in detail with reference to the accompanying drawing(s). Additionally, the present disclosure is not limited by each embodiment as illustrated below. Furthermore, it should be noted that the drawing(s) is/are schematic where a relationship(s) among dimensions of respective elements, a ratio(s) of respective elements, or the like may be different from an actual one(s). Moreover, parts where a relationship(s) among mutual dimensions and/or a ratio(s) is/are different, among mutual drawings may also be included.

A technique to remove a resist film that is formed on a substrate such as a semiconductor wafer (that will also be referred to as a wafer below) in an SPM (Sulfuric Acid Hydrogen Peroxide Mixture) process has conventionally been known. Such an SPM process is executed by supplying an SPM liquid that is produced by mixing sulfuric acid and a hydrogen peroxide solution to a resist film on a substrate.

Furthermore, in a conventional technique, a technique to discharge a water vapor at a high temperature to a substrate prior to discharge of an SPM liquid and execute an SPM process under a high temperature environment so that the SPM process is executed efficiently is disclosed.

On the other hand, in a conventional technique as described above, in a case where an impurity/impurities is/are incorporated in a water vapor, such an impurity/impurities may be attached to a substrate so as to contaminate the substrate.

Hence, a technique is expected that is capable of overcoming a problem(s) as described above and preventing or reducing contamination of a substrate in a liquid process such as an SPM process.

### Outline of Substrate Processing System

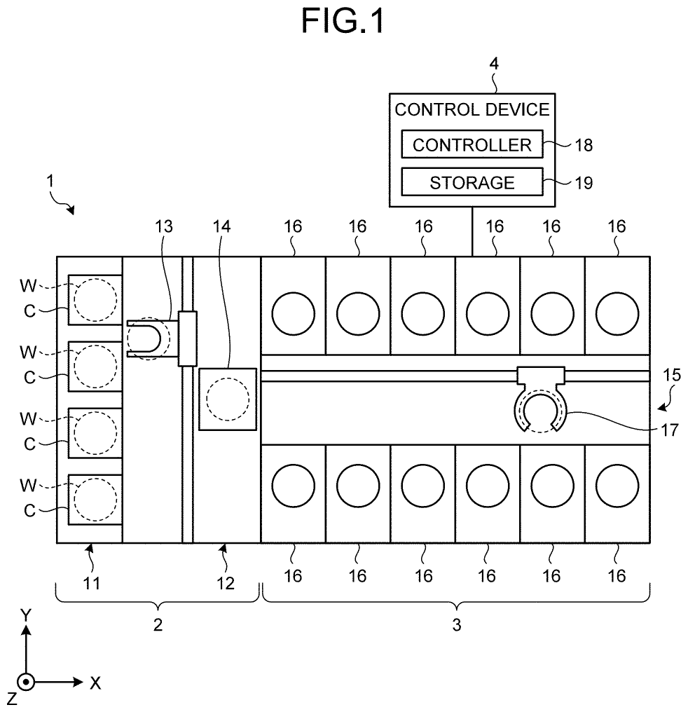

First, a general configuration of a substrate processing system 1 according to an embodiment will be explained with reference to FIG. 1. FIG. 1 is a diagram that illustrates a general configuration of a substrate processing system 1 according to an embodiment. Additionally, the substrate processing system 1 is an example of a substrate processing apparatus. Hereinafter, in order to clarify a positional relationship, an X-axis, a Y-axis, and a Z-axis that are orthogonal to one another are defined and a positive direction of the Z-axis is provided as a vertically upward direction.

As illustrated in FIG. 1, the substrate processing system 1 includes a carry-in/out station 2 and a processing station 3. The carry-in/out station 2 and the processing station 3 are provided adjacently.

The carry-in/out station 2 includes a carrier placing section 11 and a transfer section 12. On the carrier placing section 11, a plurality of carriers C are placed that house a plurality of substrates, in an embodiment, semiconductor wafers W (that will be referred to as wafers W below), in a horizontal state thereof.

The transfer section 12 is provided so as to be adjacent to the carrier placing section 11 and includes a substrate transfer device 13 and a delivery unit 14 in an inside thereof. The substrate transfer device 13 includes a wafer holding mechanism that holds a wafer W. Furthermore, the substrate transfer device 13 is capable of moving in a horizontal direction and a vertical direction and pivoting around a vertical axis as a center thereof, and executes transfer of a wafer W between a carrier C and the delivery unit 14 by using a wafer holding mechanism.

The processing station 3 is provided so as to be adjacent to the transfer section 12. The processing station 3 includes a transfer unit 15 and a plurality of processing units 16. A processing unit 16 is an example of a substrate processing unit. The plurality of processing units 16 are provided side by side on both sides of the transfer unit 15.

The transfer unit 15 includes a substrate transfer device 17 in an inside thereof. The substrate transfer device 17 includes a wafer holding mechanism that holds a wafer W. Furthermore, the substrate transfer device 17 is capable of moving in a horizontal direction and a vertical direction and pivoting around a vertical axis as a center thereof, and executes transfer of a wafer W between the delivery unit 14 and a processing unit 16 by using a wafer holding mechanism.

A processing unit 16 executes predetermined substrate processing for a wafer W that is transferred by the substrate transfer device 17. A detail(s) of such a processing unit 16 will be described later.

Furthermore, the substrate processing system 1 includes a control device 4. The control device 4 is, for example, a computer, and includes a controller 18 and a storage 19. The storage 19 stores therein a program that controls a variety of processes that are executed in the substrate processing system 1. The controller 18 reads and executes a program that is stored in the storage 19 so as to control an operation of the substrate processing system 1.

Additionally, such a program may be recorded in a computer-readable storage medium and be installed from such a storage medium to the storage 19 of the control device 4. For a computer-readable storage medium, for example, a hard disk (HD), a flexible disk (FD), a compact disk (CD), a magnetooptical disk (MO), a memory card, or the like is provided.

In the substrate processing system 1 that is configured as described above, first, the substrate transfer device 13 of the carry-in/out station 2 takes a wafer W from a carrier C that is placed on the carrier placing section 11 and places a taken wafer W on the delivery unit 14. A wafer W that is placed on the delivery unit 14 is taken from the delivery unit 14 by the substrate transfer device 17 of the processing station 3 and is carried in a processing unit 16.

A wafer W that is carried in a processing unit 16 is processed by the processing unit 16, subsequently is carried out of the processing unit 16 by the substrate transfer device 17, and is placed on the delivery unit 14. Then, a processed wafer W that is placed on the delivery unit 14 is returned to a carrier C of the carrier placing section 11 by the substrate transfer device 13.

### Configuration of Processing Unit

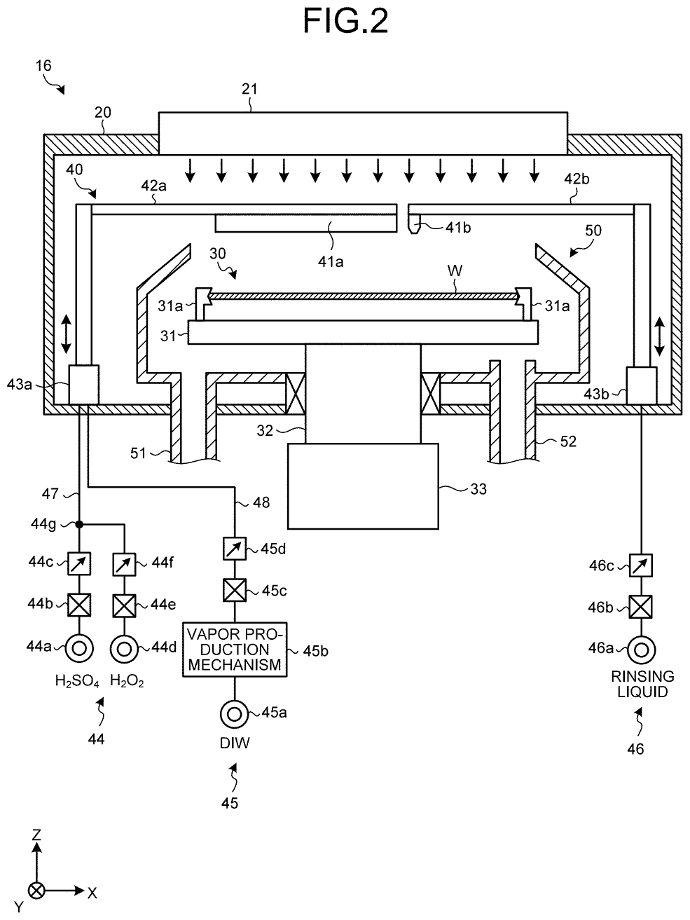

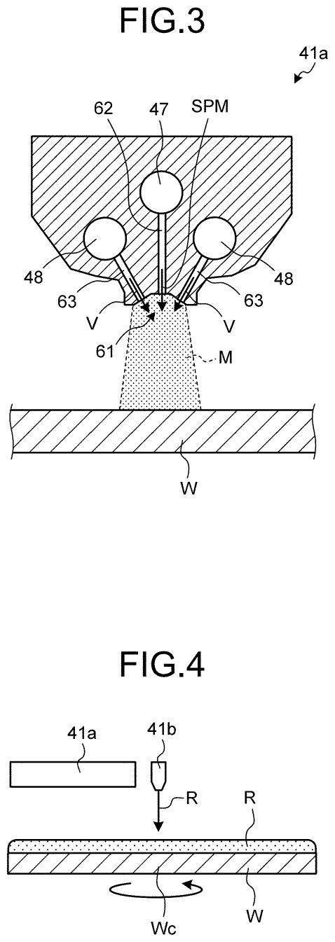

Next, a configuration of a processing unit 16 will be explained with reference to FIG. 2 and FIG. 3. FIG. 2 is a schematic diagram that illustrates a configuration example of a processing unit 16 according to an embodiment. As illustrated in FIG. 2, the processing unit 16 includes a chamber 20, a liquid processing unit 30, a liquid supply unit 40, and a recovery cup 50.

The chamber 20 houses the liquid processing unit 30, the liquid supply unit 40, and the recovery cup 50. An FFU (Fun Filter unit) 21 is provided on a ceiling part of the chamber 20. The FFU 21 forms a downflow in the chamber 20.

The liquid processing unit 30 includes a holding unit 31, a supporting unit 32, and a driving unit 33, and applies a liquid process to a placed wafer W. The holding unit 31 holds a wafer W horizontally. The supporting unit 32 is a member that extends in a vertical direction where a proximal end part thereof is supported by the driving unit 33 so as to be rotatable and a distal end part thereof supports the holding unit 31 horizontally. The driving unit 33 rotates the supporting unit 32 around a vertical axis thereof.

Such a liquid processing unit 30 rotates the supporting unit 32 by using the driving unit 33 so as to rotate the holding unit 31 that is supported by the supporting unit 32 and thereby rotate a wafer W that is held by the holding unit 31.

A holding member 31a that holds a wafer W on a side surface thereof is provided on an upper surface of the holding unit 31 that is included in the liquid processing unit 30. A wafer W is held horizontally by such a holding member 31a in a state where it is slightly separated from an upper surface of the holding unit 31. Additionally, a wafer W is held by the holding unit 31 in a state where a surface where substrate processing is executed is oriented upward.

The liquid supply unit 40 supplies a processing liquid to a wafer W. The liquid supply unit 40 includes nozzles 41a, 41b, arms 42a, 42b that horizontally support such nozzles 41a, 41b, respectively, and turning/lifting mechanisms 43a, 43b that that turn and lift the arms 42a, 42b, respectively. A nozzle 41a is an example of a liquid discharge unit.

The nozzle 41a is, for example, a bar nozzle, is connected to an SPM liquid supply unit 44 through an SPM liquid supply route 47, and is connected to a water vapor supply unit 45 through a water vapor supply route 48. The SPM liquid supply unit 44 is an example of a first supply unit and the water vapor supply unit 45 is an example of a second supply unit.

An SPM liquid that is supplied from the SPM liquid supply unit 44 is an example of a processing liquid, and is a chemical liquid is produced by mixing sulfuric acid (H₂SO₄) and a hydrogen peroxide solution (H₂O₂) at a predetermined proportion (for example, H₂SO₄:H₂O₂=10:1). An SPM liquid is used for, for example, a removal process for a resist film that is formed on a surface of a wafer W.

The SPM liquid supply unit 44 has a sulfuric acid supply source 44a, a valve 44b, a flow volume regulator 44c, a hydrogen peroxide solution supply source 44d, a valve 44e, a flow volume regulator 44f, and a junction part 44g.

The sulfuric acid supply source 44a supplies sulfuric acid that is held at a predetermined temperature (for example, 120° C.) to the junction part 44g through the valve 44b and the flow volume regulator 44c. The flow volume regulator 44c regulates a flow volume of sulfuric acid that is supplied to the junction part 44g.

The hydrogen peroxide solution supply source 44d supplies a hydrogen peroxide solution to the junction part 44g through the valve 44e and the flow volume regulator 44f. The flow volume regulator 44f regulates a flow volume of a hydrogen peroxide solution that is supplied to the junction part 44g. Furthermore, the junction part 44g is connected to the SPM liquid supply route 47.

Then, an SPM liquid that is produced by mixing sulfuric acid and a hydrogen peroxide solution at the junction part 44g is supplied to the nozzle 41a through the SPM liquid supply route 47. Additionally, when sulfuric acid and a hydrogen peroxide solution are mixed, an SPM liquid produces heat, so that a temperature thereof is raised to a temperature (for example, 140° C.) that is higher than a temperature of sulfuric acid at a time when reaching the nozzle 41a.

The water vapor supply unit 45 has a DIW supply source 45a, a vapor production mechanism 45b, a valve 45c, and a flow volume regulator 45d.

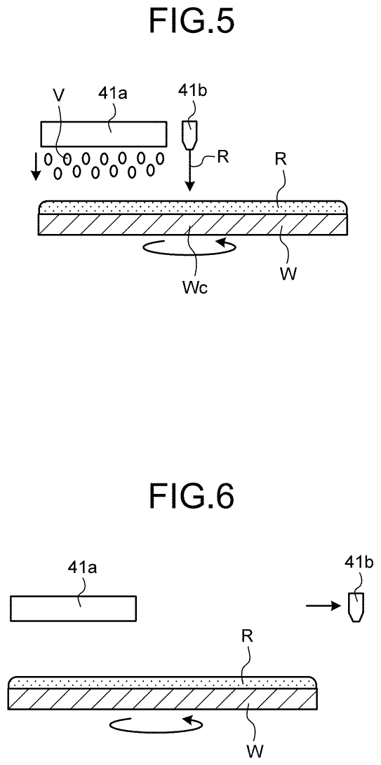

The DIW supply source 45a supplies a DIW (Deionized Water: a deionized water) to the vapor production mechanism 45b. The vapor production mechanism 45b produces a water vapor V (see FIG. 5) where a DIW that is supplied from the DIW supply source 45a is a raw material thereof. A water vapor V is an example of a purified water in a vapor state thereof.

The flow volume regulator 45d regulates a flow volume of a water vapor V that is supplied to the water vapor supply route 48 through the valve 45c. Then, a water vapor V that is produced in the water vapor supply unit 45 is supplied to the nozzle 41a through the water vapor supply route 48.

FIG. 3 is a cross-sectional view that illustrates a configuration example of a nozzle 41a according to an embodiment. As illustrated in FIG. 3, one SPM liquid supply route 47 and two water vapor supply routes 48 are inserted into an inside of the nozzle 41a side by side along a longitudinal direction of the nozzle 41a.

Furthermore, a discharge route 62 is connected between a discharge port 61 that is formed on a lower surface of the nozzle 41a and the SPM liquid supply route 47 and a discharge route(s) 63 is/are connected between the discharge port 61 and a water vapor supply route(s) 48.

That is, an SPM liquid (that will be described as SPM in the undermentioned drawing(s)) is supplied to the discharge port 61 of the nozzle 41a through the discharge route 62 and a water vapor V is supplied thereto through the discharge route(s) 63.

Then, in the nozzle 41a according to an embodiment, an SPM liquid and a water vapor V are mixed at the discharge port 61 so as to produce a mixed fluid M thereof. That is, in the present disclosure, a mixed fluid M is produced by mixing an SPM liquid and a water vapor V after being discharged from the nozzle 41a and before reaching a wafer W. Additionally, a plurality of discharge ports 61 are arranged side by side along a longitudinal direction of the nozzle 41a.

Thereby, it is possible for the nozzle 41a according to an embodiment to discharge a mixed fluid M that is produced by mixing an SPM liquid and a water vapor V, from the plurality of discharge ports 61 to a wafer W. Furthermore, in such a mixed fluid M, a temperature of an SPM liquid is raised by a water vapor V (for example, 160° C. to 200° C.)

Therefore, according to an embodiment, a surface of a wafer W is processed by a mixed fluid M where a temperature of an SPM liquid is raised, so that it is possible to remove a resist film that is formed on a surface of the wafer W efficiently.

An explanation of FIG. 2 is returned to. A nozzle 41b is connected to a rinsing liquid supply unit 46. A rinsing liquid R (see FIG. 4) that is supplied from the rinsing liquid supply unit 46 is used for, for example, a rinsing process. A rinsing liquid R according to an embodiment is, for example, a hydrogen peroxide solution, a DIW, an ozone water, a diluted ammonia water, and the like.

The rinsing liquid supply unit 46 has a rinsing liquid supply source 46a, a valve 46b, and a flow volume regulator 46c. The rinsing liquid supply source 46a supplies a rinsing liquid R to the nozzle 41b. The flow volume regulator 46c regulates a flow volume of a rinsing liquid R that is supplied to the nozzle 41b through the valve 46b.

The recovery cup 50 is arranged so as to surround the holding unit 31 and collects a processing liquid that is scattered from a wafer W by rotation of the holding unit 31. A drain port 51 is formed on a bottom part of the recovery cup 50 and a processing liquid that is collected by the recovery cup 50 is discharged from such a drain port 51 to an outside of the processing unit 16.

Furthermore, an exhaust port 52 that discharges a gas that is supplied from the FFU 21 to an outside of the processing unit 16 is formed on a bottom part of the recovery cup 50.

### Detail(s) of Substrate Processing

Next, a detail(s) of substrate processing according to an embodiment will be explained with reference to FIG. 4 to FIG. 9. FIG. 4 to FIG. 9 are schematic diagrams that illustrate a step of substrate processing according to an embodiment.

First, a controller 18 (see FIG. 1) holds a wafer W by a holding unit 31 (see FIG. 2), as illustrated in FIG. 4. Then, the controller 18 arranges a nozzle 41b at an upper side of a central part Wc of a wafer W and arranges a nozzle 41a at an upper side of the wafer W and in a vicinity of the nozzle 41b.

Then, the controller 18 rotates a wafer W at a predetermined rotational frequency and discharges a rinsing liquid R from the nozzle 41b to a central part Wc of the wafer W. That is, the controller 18 supplies a rinsing liquid R in such a manner that a rinsing liquid R that is spread when contacting a wafer W covers a center of the wafer W. Thereby, the controller 18 forms a liquid film of a rinsing liquid R on a whole surface of a wafer W.

Herein, in an embodiment, a water vapor V that is used in last wafer processing may cause dew condensation thereof inside a water vapor supply route(s) 48 (see FIG. 2) and such a dew-condensed water drop(s) may directly fall from the nozzle 41a onto a surface of a wafer W.

Then, in an embodiment, an impurity/impurities may be incorporated into a water vapor V in a vapor production mechanism 45b (see FIG. 2) or the like, so that a large amount of an impurity/impurities may also be included in a water drop(s) that remain(s) on a water vapor supply route(s) 48. Hence, as a water drop(s) directly fall(s) onto a surface of a wafer W, the wafer W may be contaminated with an impurity/impurities that is/are included in such a water drop(s).

However, in an embodiment, a liquid film of a rinsing liquid R is preliminarily formed on a whole surface of a wafer W, so that it is possible to execute scattering from the wafer W without directly attaching an impurity/impurities that is/are included in a water drop(s) to a surface of the wafer W.

That is, in an embodiment, it is possible to prevent or reduce directly attaching of an impurity/impurities that remain(s) on the water vapor supply route(s) 48 to a surface of a wafer W. Therefore, according to an embodiment, a liquid film of a rinsing liquid R is preliminarily formed on a whole surface of a wafer W, so that it is possible to prevent or reduce contamination of the wafer W that is caused by an impurity/impurities that is/are included in a water vapor V.

Furthermore, the controller 18 may discharge a water vapor V from the nozzle 41a toward a surface of a wafer W where a liquid film of a rinsing liquid R is formed, as illustrated in FIG. 5. That is, in a process as illustrated in FIG. 5, the nozzle 41a is not supplied with an SPM liquid but is supplied with only a water vapor V.

Thereby, it is possible to reliably push a water drop(s) that is/are produced by causing dew condensation inside the water vapor supply route(s) 48, together with a water vapor V, out of the water vapor supply route(s) 48. Therefore, according to an embodiment, it is possible to further prevent or reduce contamination of a wafer W that is caused by an impurity/impurities that is/are included in a water vapor V.

Furthermore, in an embodiment, a water vapor V is discharged from the nozzle 41a toward a surface of a wafer W where a liquid film of a rinsing liquid R is formed, so that it is possible to raise temperatures of the nozzle 41a and the water vapor supply route(s) 48. Thereby, when a water vapor V is discharged from the nozzle 41a in a subsequent process, it is possible to prevent or reduce dew condensation of such a water vapor V.

Therefore, according to an embodiment, it is possible to further prevent or reduce contamination of a wafer W that is caused by an impurity/impurities that is/are included in a water vapor V.

Furthermore, in an embodiment, temperatures of the nozzle 41a and the water vapor supply route(s) 48 are preliminarily raised by a water vapor V, so that it is possible to accelerate rising of a temperature when a water vapor V is discharged from the nozzle 41a in a subsequent process.

Then, the controller 18 stops discharge of a water vapor V from the nozzle 41a at a timing when a water drop(s) that remain(s) on the water vapor supply route(s) (see FIG. 2) is/are discharged to an outside thereof (for example, about 10 seconds from a start of discharge of a water vapor V), as illustrated in FIG. 6. Thereby, it is possible for the controller 18 to remove a water drop(s) that remain(s) on the water vapor supply route(s) 48.

Furthermore, the controller 18 also stops discharge of a rinsing liquid R from the nozzle 41b simultaneously with a stop of discharge of a water vapor V from the nozzle 41a, and moves such a nozzle 41b to a waiting position thereof. Additionally, in a process as illustrated in FIG. 6, a liquid film of a rinsing liquid R is continuously formed on a surface of a wafer W.

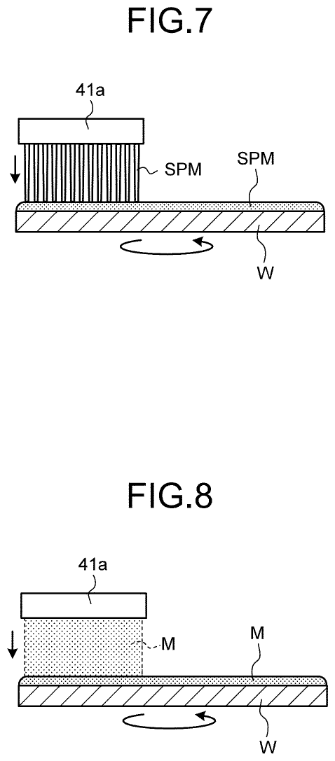

Then, the controller 18 rotates a wafer W at a predetermined first rotational frequency and discharges an SPM liquid from the nozzle 41a toward a surface of the wafer W where a liquid film of a rinsing liquid R is formed, as illustrated in FIG. 7. For example, the controller 18 discharges an SPM liquid from the nozzle 41a that is a bar nozzle to a center to a peripheral part of a wafer W where a liquid film of a rinsing liquid R is formed.

That is, in a process as illustrated in FIG. 7, the nozzle 41a is not supplied with a water vapor V but is supplied with only an SPM liquid. Thereby, the controller 18 forms a liquid film of an SPM liquid on a surface of a wafer W.

Herein, in an embodiment, an SPM liquid is discharged toward a surface of a wafer W where a liquid film of a rinsing liquid R is formed, so that it is possible to spread an SPM liquid with a comparatively large viscosity over a whole surface of the wafer W quickly.

That is, in an embodiment, an SPM liquid with a large viscosity is non-uniformly spread on a surface of a wafer W, so that it is possible to prevent or reduce liquid splashing of such an SPM liquid at the holding member 31a (see FIG. 2) or the like. Therefore, according to an embodiment, it is possible to prevent or reduce contamination of a wafer W that is caused by such liquid splashing.

Then, the controller 18 starts discharge of a mixed fluid M from the nozzle 41a at a timing when an SPM liquid is spread over a whole surface of a wafer W (for example, about 3 seconds from a start of discharge of an SPM liquid), as illustrated in FIG. 8. For example, the controller 18 discharges a mixed fluid M from the nozzle 41a that is a bar nozzle to a center to a peripheral part of a wafer W.

That is, in a process as illustrated in FIG. 8, any of an SPM liquid and a water vapor V is supplied to the nozzle 41a. Thereby, the controller 18 forms a liquid film of a mixed fluid M on a surface of a wafer W.

Then, in an embodiment, a wafer W is SPM-processed by an SPM liquid at a temperature that is raised by a water vapor V, so that it is possible to remove a resist film that is formed on a surface of a wafer W efficiently.

Furthermore, the controller 18, in an SPM process, first or previously discharges only an SPM liquid from the nozzle 41a, and then, additionally discharges a water vapor V from the nozzle 41a, as illustrated in FIG. 7 and FIG. 8. That is, the controller 18 additionally discharges a water vapor V to a surface of a wafer W where a liquid film of an SPM liquid is formed.

Thereby, it is possible for the controller 18 to execute scattering from a wafer W without causing an impurity/impurities that is/are included in a water vapor V to attach to a surface of the wafer W directly.

That is, in an embodiment, it is possible to prevent or reduce directly attaching of an impurity/impurities that is/are included in a water vapor V to a surface of a wafer W. Therefore, according to an embodiment, it is possible to prevent or reduce contamination of a wafer W in a liquid process such as an SPM process.

Furthermore, in an embodiment, it is preferable that the controller 18 executes a process that discharges only a water vapor V from the nozzle 41a (see FIG. 5) prior to an SPM process. Thereby, when a mixed fluid M is produced by the nozzle 41a, it is possible to prevent or reduce bumping and liquid splashing that are caused by reaction between a water drop(s) that remain(s) on the water vapor supply route(s) 48 and an SPM liquid.

Therefore, according to an embodiment, it is possible to prevent or reduce contamination of a wafer W that is caused by such liquid splashing.

Furthermore, in an embodiment, it is preferable that a rotational frequency of a wafer W in a discharge process for a mixed fluid M as illustrated in FIG. 8 is a second rotational frequency that is less than a first rotational frequency in a discharge process for an SPM liquid as illustrated in FIG. 7. That is, in an embodiment, it is preferable that a discharge process for an SPM liquid is executed at a greater first rotational frequency and a discharge process for a mixed fluid M is executed at a less second rotational frequency.

Thus, as a discharge process for an SPM liquid is executed at a greater first rotational frequency, it is possible to form a liquid film of an SPM liquid on a whole surface of a wafer W quickly, so that it is possible to transfer to a discharge process for a mixed fluid M quickly.

Furthermore, as a discharge process for a mixed fluid M is executed at a less second rotational frequency, it is possible to increase a duration of contact between a surface of a wafer W and a mixed fluid M, so that it is possible to remove a resist film that is formed on a surface of a wafer W more efficiently.

That is, in an embodiment, a discharge process for a mixed fluid M is executed at a second rotational frequency that is less than a first rotational frequency, so that it is possible to remove a resist film for a short processing time efficiently.

Additionally, in an embodiment, a discharge process for an SPM liquid as illustrated in FIG. 7 may be executed at a greater first discharge flow volume and a discharge process for a mixed fluid M as illustrated in FIG. 8 may be executed at a less second discharge flow volume. Thereby, it is also possible to remove a resist film for a short processing time efficiently.

Furthermore, in an embodiment, it is preferable that, when a discharge process for a mixed fluid M as illustrated in FIG. 8 is ended, supply of a water vapor V is stopped prior to an SPM liquid. If supply of an SPM liquid is stopped prior to a water vapor V, it is possible for a water vapor V that includes an impurity/impurities to attach to a surface of a wafer W directly, so that the wafer W may be contaminated.

On the other hand, in an embodiment, supply of a water vapor V is stopped prior to an SPM liquid, so that it is possible to prevent or reduce directly attaching of a water vapor V that includes an impurity/impurities to a surface of a wafer W. Therefore, according to an embodiment, it is possible to prevent or reduce contamination of a wafer W that is caused by an impurity/impurities that is/are included in a water vapor V.

Additionally, in an embodiment, when a discharge process for a mixed fluid M is ended, a case where supply of a water vapor V is stopped prior to an SPM liquid is not limiting and supply of an SPM liquid and supply of a water vapor V may be stopped simultaneously.

Thereby, it is also possible to prevent or reduce directly attaching of a water vapor V that includes an impurity/impurities to a surface of a wafer W, so that it is possible to prevent or reduce contamination of a wafer W that is caused by an impurity/impurities that is/are included in a water vapor V.

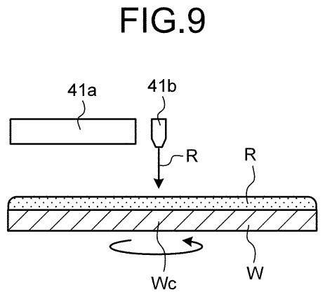

After a discharge process for a mixed fluid M as thus far explained is ended, the controller 18 moves the nozzle 41b to an upper side of a central part We of a wafer W and discharges a rinsing liquid R from such a nozzle 41b to the wafer W, as illustrated in FIG. 9. That is, the controller 18 supplies a rinsing liquid R in such a manner that a rinsing liquid R that is spread when contacting a wafer W covers a center of the wafer W. Thereby, the controller 18 executes a rinsing process for a wafer W.

Additionally, in an embodiment, a rinsing process for a wafer W as illustrated in FIG. 9 may be executed by a hydrogen peroxide solution. That is, in an embodiment, a hydrogen peroxide solution may be used as a rinsing liquid R. Thereby, it is possible to execute a rinsing process for a wafer W efficiently.

Then, the controller 18 executes a drying process (for example, spin drying) for a wafer W or the like following such a rinsing process so as to complete a series of substrate processing.

Additionally, although an example where an SPM liquid is used as a processing liquid that is provided as a raw material of a mixed fluid M, together with a water vapor V, has been illustrated in an embodiment as described above, the present disclosure is not limited to such an example. For example, a diluted sulfuric acid, a mixed liquid of sulfuric acid and an ozone water, phosphoric acid, SC1 (a mixed liquid of ammonia and a hydrogen peroxide solution), a DHF (diluted hydrofluoric acid), a mixed liquid of fluoronitric acid and a hydrogen peroxide solution, and the like may be used as a processing liquid that is provided as a raw material of a mixed fluid M, together with a water vapor V.

On the other hand, an SPM liquid is used as a processing liquid that is provided as a raw material of a mixed fluid M, together with a water vapor V, so that it is possible to execute an SPM process at a high temperature and hence it is possible to remove a resist film that is formed on a surface of a wafer W efficiently.

### Variation 1

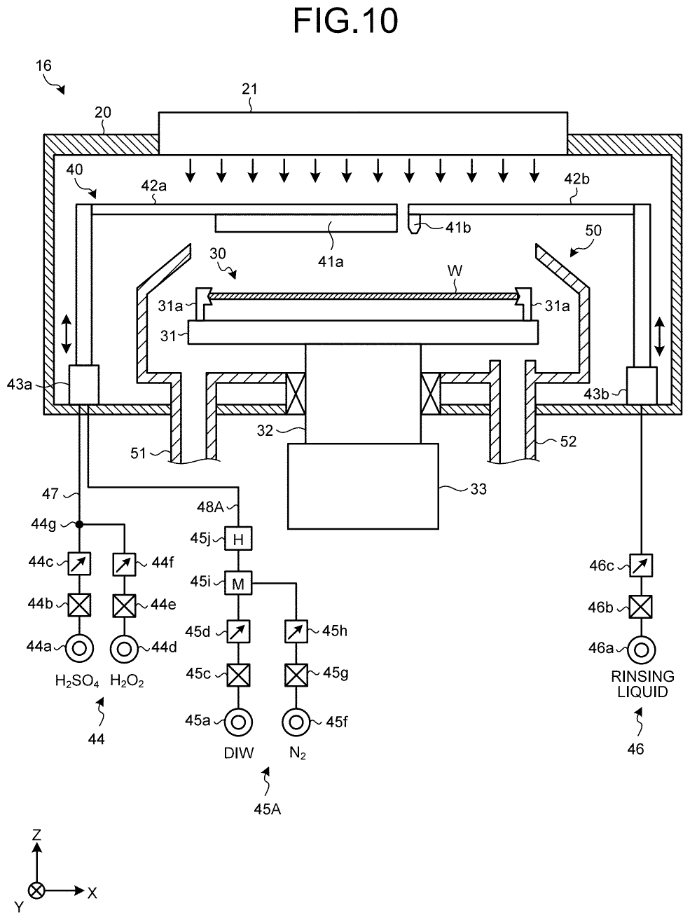

Next, various types of variations of an embodiment will be explained with reference to FIG. 10 to FIG. 15. FIG. 10 is a schematic diagram that illustrates a configuration example of a processing unit 16 according to variation 1 of an embodiment.

As illustrated in FIG. 10, the processing unit 16 according to variation 1 is different from an embodiment in that a water mist supply unit 45A is provided instead of a water vapor supply unit 45. Hence, in an undermentioned example(s), a site that is similar to that of an embodiment will be provided with an identical sign so as to omit a detailed explanation(s) thereof.

A nozzle 41a is, for example, a bar nozzle, is connected to an SPM liquid supply unit 44 through an SPM liquid supply route 47, and is connected to a water mist supply unit 45A through a water mist supply route 48A. The water mist supply unit 45A is another example of a second supply unit.

A water mist that is supplied from the water mist supply unit 45A is an example of a purified water in a mist state thereof, and is produced by mixing a DIW and nitrogen (N₂). Such a water mist is used in a temperature raising process for an SPM liquid similarly to a water vapor V in an embodiment.

The water mist supply unit 45A has a DIW supply source 45a, a valve 45c, a flow volume regulator 45d, a nitrogen supply source 45f, a valve 45g, a flow volume regulator 45h, a mixer 45i, and a heater 45j.

The DIW supply source 45a supplies a DIW to the mixer 45i through the valve 45c and the flow volume regulator 45d. The flow volume regulator 45d regulates a flow volume of a DIW that is supplied to the mixer 45i.

The nitrogen supply source 45f supplies a nitrogen gas to the mixer 45i through the valve 45g and the flow volume regulator 45h. The flow volume regulator 45h regulates a flow volume of a nitrogen gas that is supplied to the mixer 45i.

The mixer 45i has a function as an atomizer. In variation 1, when a DIW in a liquid state at an ordinary temperature is mixed with a nitrogen gas at an ordinary temperature in the mixer 45i, atomization is caused so as to provide a water mist and it flows out to the heater 45j on a downstream side thereof.

The heater 45j is connected to the water mist supply route 48A. Then, the heater 45j raises a temperature of a water mist that is supplied from the mixer 45i to a predetermined temperature (for example, about 100° C.) and supplies such a water mist at a raised temperature to the water mist supply route 48A.

A water mist that is supplied to the nozzle 41a through the water mist supply route 48A is discharged from a discharge port 61 (see FIG. 3) of the nozzle 41a through a discharge route 63 (see FIG. 3), similarly to a water vapor V in an embodiment. Thereby, it is possible for the processing unit 16 according to variation 1 to discharge a mixed fluid M that is produced by mixing an SPM liquid and a water mist, from the nozzle 41a to a wafer W.

Furthermore, in variation 1, a DIW in a mist state thereof is injected and subsequently is mixed with an SPM liquid, so that mixing of the SPM liquid and a water mist is completed immediately so as to achieve a speedy temperature rise that is caused by heat of hydration thereof. Therefore, according to variation 1, it is possible to remove a resist film that is formed on a surface of a wafer W efficiently, by a mixed fluid M where a temperature of an SPM liquid is raised.

Then, in variation 1, it is preferable that the controller 18 forms a liquid film of a rinsing liquid R on a surface of a wafer W prior to discharge of a water mist (see FIG. 5), similarly to an embodiment as described above. Thereby, it is possible to prevent or reduce directly discharging of a water drop(s) that is/are produced by causing dew condensation of a water mist that remains on the water mist supply route 48A to a surface of a wafer W.

Therefore, according to variation 1, it is possible to prevent or reduce remaining of a water scale or the like that is caused by such a water drop(s) on a surface of a wafer W, so that it is possible to prevent or reduce contamination of a wafer W that is caused by such a water scale or the like.

Furthermore, in variation 1, it is preferable that the controller 18, in an SPM process, first or previously discharges only an SPM liquid from the nozzle 41a, and then, additionally discharges a water mist from the nozzle 41a (see FIG. 7 and FIG. 8). That is, it is preferable that the controller 18 discharges a water mist to a surface of a wafer W where a liquid film of an SPM liquid is formed.

Thereby, it is possible for the controller 18 to prevent or reduce directly attaching of a water scale that is included in a water mist on a surface of a wafer W. Therefore, according to variation 1, it is possible to prevent or reduce contamination of a wafer W that is caused by such a water scale or the like.

Furthermore, in variation 1, it is preferable that the controller 18 executes a process that discharges only a water mist from the nozzle 41a (see FIG. 5) prior to an SPM process. Thereby, when a mixed fluid M is produced by the nozzle 41a, it is possible to prevent or reduce bumping and liquid splashing that are caused by reaction between a water drop(s) that remain(s) on the water mist supply route 48A and an SPM liquid.

Therefore, according to variation 1, it is possible to prevent or reduce contamination of a wafer W that is caused by such liquid splashing.

### Variation 2

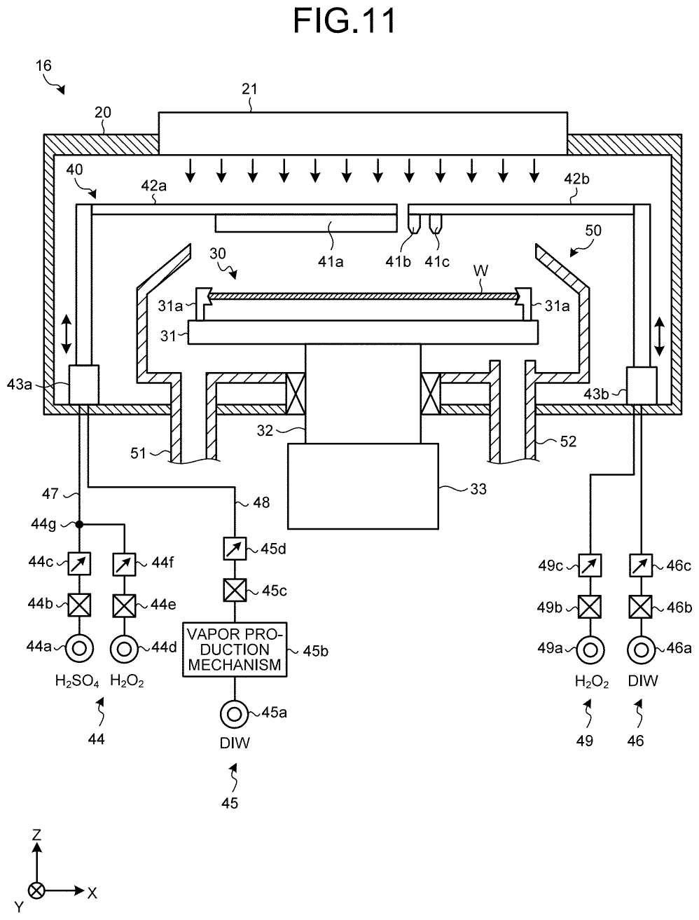

FIG. 11 is a schematic diagram that illustrates a configuration example of a processing unit 16 according to variation 2 of an embodiment. As illustrated in FIG. 11, the processing unit 16 according to variation 2 is different from an embodiment in that a nozzle 41c is further provided on an arm 42b and a hydrogen peroxide solution supply unit 49 that is connected to such a nozzle 41c is provided.

The hydrogen peroxide solution supply unit 49 has a hydrogen peroxide solution supply source 49a, a valve 49b, and a flow volume regulator 49c. The hydrogen peroxide solution supply source 49a supplies a hydrogen peroxide solution to the nozzle 41c through the valve 49b and the flow volume regulator 49c. The flow volume regulator 49c regulates a flow volume of a hydrogen peroxide solution that is supplied to the nozzle 41c.

Furthermore, in variation 2, a DIW as a rinsing liquid R (see FIG. 13) is supplied from a rinsing liquid supply source 46a of a rinsing liquid supply unit 46 to a nozzle 41b.

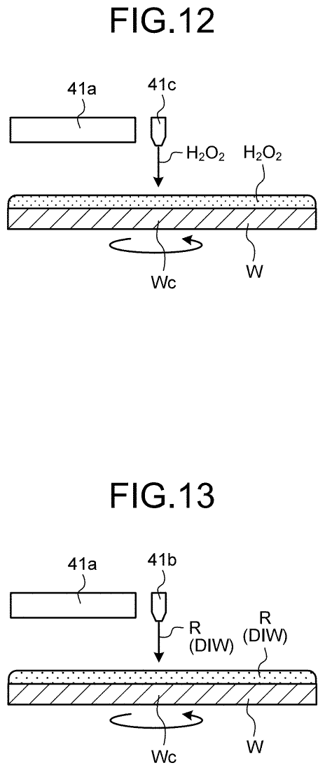

FIG. 12 and FIG. 13 are schematic diagrams that illustrate a step of substrate processing according to variation 2 of an embodiment. Additionally, various types of processes to a discharge process for a mixed fluid M as illustrated in FIG. 8 in substrate processing according to variation 2 is similar to those of an embodiment so as to omit an explanation(s) thereof.

Following a discharge process for a mixed fluid M as illustrated in FIG. 8, the controller 18 moves the nozzle 41c to an upper side of a central part We of a wafer W and discharges a hydrogen peroxide solution from such a nozzle 41c to the wafer W, as illustrated in FIG. 12. Thereby, the controller 18 processes a surface of a wafer W by a hydrogen peroxide solution.

Thereby, in variation 2, in a case where a sulfur (S) component that is included in an SPM liquid that is used for an SPM process remains on a surface of a wafer W, such a sulfur component and a hydrogen peroxide solution are reacted, so that it is possible to remove the sulfur component from a surface of the wafer W.

Then, the controller 18 moves the nozzle 41b to an upper side of a central part of a wafer W and discharges a rinsing liquid R that is a DIW from such a nozzle 41b to the wafer W, as illustrated in FIG. 13. Thereby, the controller 18 executes a rinsing process for a wafer W.

Furthermore, in variation 2, it is possible for such a rinsing process to remove a sulfur component that reacts with a hydrogen peroxide solution from a surface of the wafer W.

As thus far explained, in variation 2, a hydrogen peroxide solution discharge process and a rinsing process are continuously executed after a discharge process for a mixed fluid M, so that it is possible to further clean a surface of a wafer W where a liquid process such as an SPM process is applied.

### Variation 3

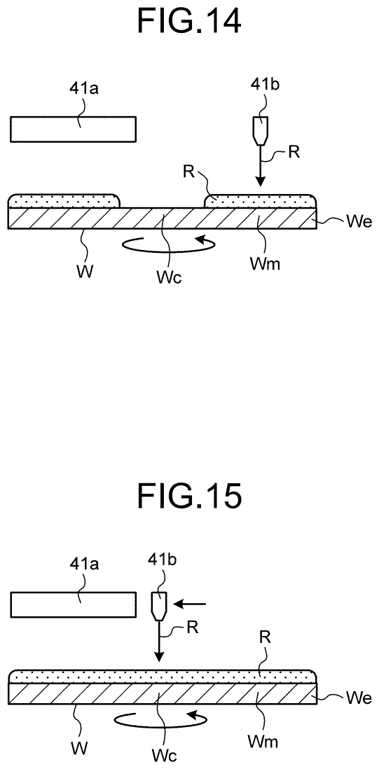

FIG. 14 and FIG. 15 are schematic diagrams that illustrate a step of substrate processing according to variation 3 of an embodiment. Additionally, a variety of processes to a discharge process for a mixed fluid M as illustrated in FIG. 8 in substrate processing according to variation 3 are similar to those of an embodiment, so that an explanation(s) thereof will be omitted.

Following a discharge process for a mixed fluid M as illustrated in FIG. 8, the controller 18 moves a nozzle 41b to an upper side of a middle part Wm between a central part Wc and a peripheral part We of a wafer W and discharges a rinsing liquid R from such a nozzle 41b to the wafer W, as illustrated in FIG. 14.

That is, the controller 18 supplies a rinsing liquid R in such a manner that the rinsing liquid R that is spread when contacting a wafer W covers a middle part Wm and a peripheral part We of the wafer W. Thereby, the controller 18 executes a rinsing process for a wafer W.

Such a middle part Wm of a wafer W is, for example, a site that is a predetermined distance away from a peripheral part We (for example, about 50 (mm) from the peripheral part We) of the wafer W toward a central part Wc thereof.

Then, the controller 18 gradually moves the nozzle 41b from an upper side of a middle part Wm to an upper side of a central part Wc of a wafer and continues discharge of a rinsing liquid R from such a nozzle 41b (a so-called scan-in operation) as illustrated in FIG. 15. Thereby, it is also possible for the controller 18 to apply a rinsing process to a central part Wc of a wafer W.

For example, for a wafer W at very high temperature (for example, about 200 (° C.)) immediately after an SPM process, in a case where a ringing liquid R at a room temperature is discharged to a central part Wc of the wafer W in a rinsing process for a wafer W, a temperature difference between the central part Wc and a peripheral part We of the wafer W is greatly increased.

Hence, in such a case, whereas a peripheral part We of a wafer W is stretched greatly, a central part Wc thereof is contracted rapidly, so that fluttering of a wafer W may be caused at an initial stage of a rinsing process. In particular, in an SPM process that uses a bar nozzle, temperatures of a central part Wc and a peripheral part We of a wafer W are substantially equal, so that such fluttering may significantly be caused at an initial stage of a rinsing process.

Hence, in this variation 3, in a rinsing process for a wafer W, a rinsing liquid R is first discharged to a middle part Wm of the wafer W that is nearer a peripheral part We than a central part Wc. Thereby, it is possible to decrease a temperature difference between a central part Wc and a peripheral part We of a wafer W at an initial stage of a rinsing process.

Therefore, according to variation 3, it is possible to prevent or reduce causing of fluttering of a wafer W at an initial stage of a rinsing process that is executed immediately after an SPM process that uses a bar nozzle.

Additionally, although an example where a rinsing process that is executed immediately after an SPM process where a wafer W is provided in a high temperature state thereof is executed by a scan-in operation has been illustrated in an example of FIG. 14 and FIG. 15, the present disclosure is not limited such an example. For example, discharge of a hydrogen peroxide solution may be executed by a scan-in operation in a removal process for a sulfur component that is executed immediately after an SPM process where a wafer W is provided in a high temperature state thereof and by a hydrogen peroxide solution.

A substrate processing apparatus according to an embodiment (a substrate processing system 1) includes a holding unit 31, a liquid discharge unit (a nozzle 41a), a first supply unit (an SPM liquid supply unit 44), a second supply unit (a water vapor supply unit 45, a water mist supply unit 45A), and a controller 18. The holding unit 31 holds a substrate (a wafer W). The liquid discharge unit (the nozzle 41a) discharges a fluid to the substrate (the wafer W) that is held by the holding unit 31. The first supply unit (the SPM liquid supply unit 44) supplies a processing liquid (an SPM liquid that is produced by mixing sulfuric acid and a hydrogen peroxide solution) to the liquid discharge unit (the nozzle 41a). The second supply unit (the water vapor supply unit 45, the water mist supply unit 45A) supplies a purified water in a vapor state or a mist state thereof to the liquid discharge unit (the nozzle 41a). The controller 18 controls each unit. Furthermore, the controller 18 discharges a processing liquid (an SPM liquid) from the liquid discharge unit (the nozzle 41a) to the substrate (the wafer W) that is held by the holding unit 31. Moreover, the controller 18 discharges a mixed fluid M that is produced by mixing a processing liquid (an SPM liquid) and a purified water in a vapor state or a mist state thereof, from the liquid discharge unit (the nozzle 41a) to the substrate (the wafer W) where a processing liquid (an SPM liquid) is discharged. Thereby, it is possible to prevent or reduce contamination of a wafer W in an SPM process.

### Procedure of Substrate Processing

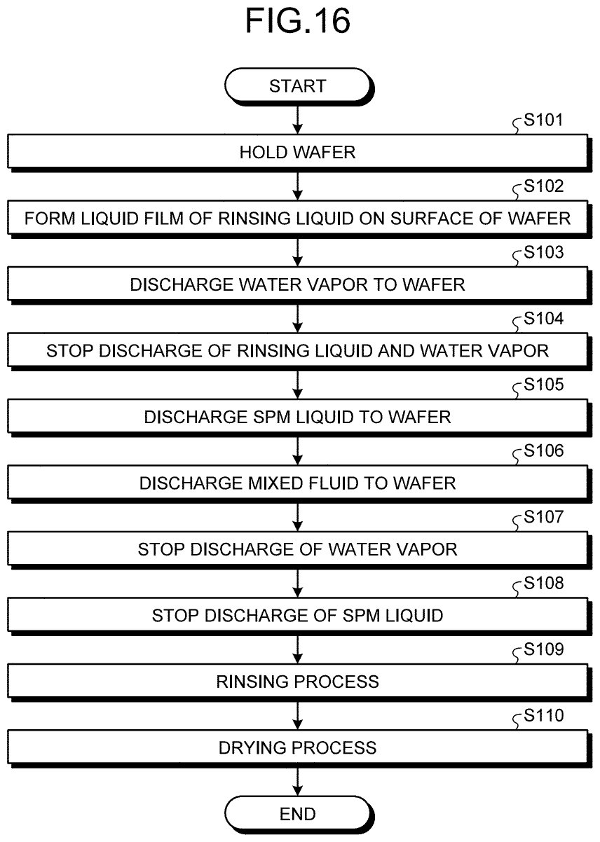

Next, procedures of substrate processing according to an embodiment and various types of variations will be explained with reference to FIG. 16 to FIG. 18. FIG. 16 is a flowchart that illustrates a procedure of substrate processing that is executed by a substrate processing system 1 according to an embodiment.

First, a controller 18 controls a processing unit 16 and the like so as to hold a wafer W by a holding unit (step S101). Then, the controller 18 controls a rinsing liquid supply unit 46 and the like so as to discharge a rinsing liquid R to a rotating wafer W. Thereby, the controller 18 forms a liquid film of a rinsing liquid R on a surface of a wafer W (step S102).

Then, the controller 18 controls a water vapor supply unit 45 and the like so as to discharge a water vapor V to a wafer W (step S103). Thereby, the controller 18 discharges a water drop(s) that remain(s) on a water vapor supply route 48 to an outside thereof.

Then, the controller 18 controls the water vapor supply unit 45, the rinsing liquid supply unit 46, and the like so as to stop discharge of a rinsing liquid R and a water vapor V to a wafer W (step S104). Then, the controller 18 controls the SPM liquid supply unit 44 and the like so as to discharge an SPM liquid to a wafer W (step S105).

Then, the controller 18 controls the SPM liquid supply unit 44, the water vapor supply unit 45, and the like so as to supply both an SPM liquid and a water vapor V to a nozzle 41a and thereby discharge a mixed fluid M to a wafer W (step S106).

Then, the controller 18 controls the water vapor supply unit 45 and the like so as to stop discharge of a water vapor V from the nozzle 41a (step S107) and subsequently controls the SPM liquid supply unit 44 and the like so as to stop discharge of an SPM liquid from the nozzle 41a (step S108).

Then, the controller 18 controls the rinsing liquid supply unit 46 and the like so as to execute a rinsing process for a wafer W by a rinsing liquid R (step S109). Additionally, such a process at step S109 may be executed by scan-in-operating a nozzle 41b. Then, the controller 18 controls a processing unit 16 so as to execute a drying process (for example, spin drying) for a wafer W (step S110) and complete a series of substrate processing.

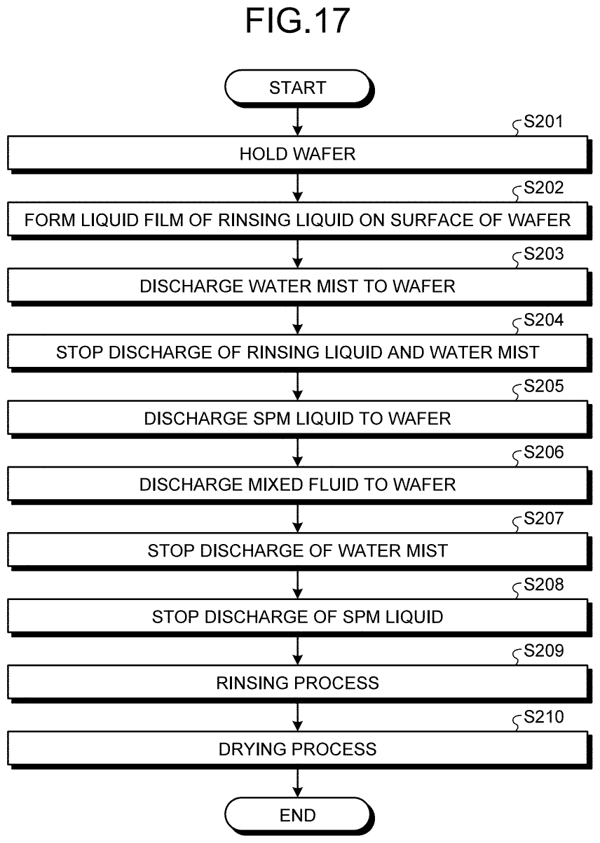

FIG. 17 is a flowchart that illustrates a procedure of substrate processing that is executed by a substrate processing system 1 according to variation 1 of an embodiment.

First, a controller 18 controls a processing unit 16 and the like so as to hold a wafer W by a holding unit (step S201). Then, the controller 18 controls a rinsing liquid supply unit 46 and the like so as to discharge a rinsing liquid R to a rotating wafer W. Thereby, the controller 18 forms a liquid film of a rinsing liquid R on a surface of a wafer W (step S202).

Then, the controller 18 controls a water mist supply unit 45A and the like so as to discharge a water mist to a wafer W (step S203). Thereby, the controller 18 discharges a water drop(s) that remain(s) on a water mist supply route 48A to an outside thereof.

Then, the controller 18 controls the water mist supply unit 45A, the rinsing liquid supply unit 46, and the like so as to stop discharge of a rinsing liquid R and a water mist to a wafer W (step S204). Then, the controller 18 controls a SPM liquid supply unit 44 and the like so as to discharge an SPM liquid to a wafer W (step S205).

Then, the controller 18 controls the SPM liquid supply unit 44, the water mist supply unit 45A, and the like so as to supply both an SPM liquid and a water mist to a nozzle 41a and thereby discharge a mixed fluid M to a wafer W (step S206).

Then, the controller 18 controls the water mist supply unit 45A and the like so as to stop discharge of a water mist from the nozzle 41a (step S207) and subsequently controls the SPM liquid supply unit 44 and the like so as to stop discharge of an SPM liquid from the nozzle 41a (step S208).

Then, the controller 18 controls the rinsing liquid supply unit 46 and the like so as to execute a rinsing process for a wafer W by a rinsing liquid R (step S209). Additionally, such a process at step S209 may be executed by scan-in-operating the nozzle 41b. Then, the controller 18 controls a processing unit 16 so as to execute a drying process (for example, spin drying) for a wafer W (step S210) and complete a series of substrate processing.

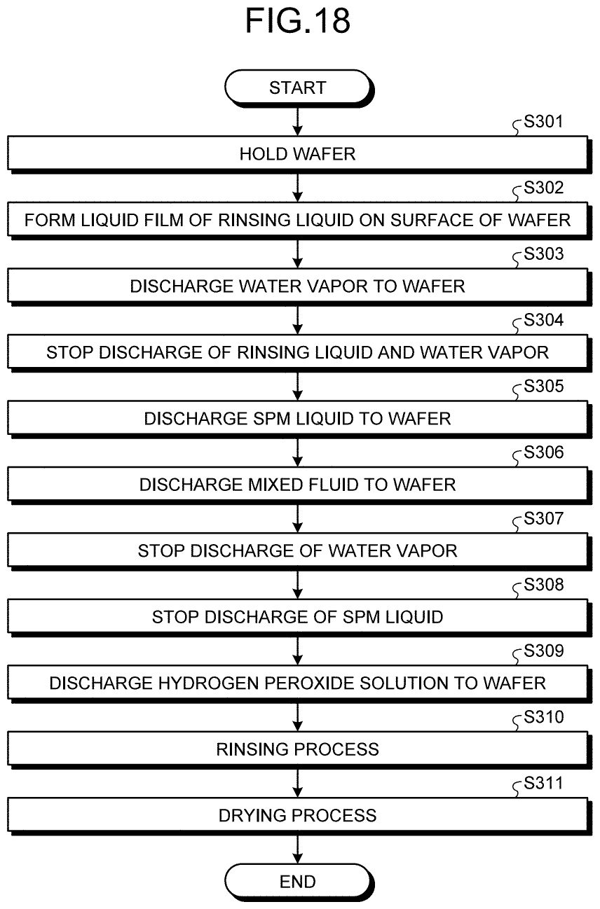

FIG. 18 is a flowchart that illustrates a procedure of substrate processing that is executed by a substrate processing system 1 according to variation 2 of an embodiment.

First, a controller 18 controls a processing unit 16 and the like so as to hold a wafer W by a holding unit (step S301). Then, the controller 18 controls a rinsing liquid supply unit 46 and the like so as to discharge a rinsing liquid R to a rotating wafer W. Thereby, the controller 18 forms a liquid film of a rinsing liquid R on a surface of a wafer W (step S302).

Then, the controller 18 controls a water vapor supply unit 45 and the like so as to discharge a water vapor V to a wafer W (step S303). Thereby, the controller 18 discharges a water drop(s) that remain(s) on a water vapor supply route 48 to an outside thereof.

Then, the controller 18 controls the water vapor supply unit 45, the rinsing liquid supply unit 46, and the like so as to stop discharge of a rinsing liquid R and a water vapor V to a wafer W (step S304). Then, the controller 18 controls a SPM liquid supply unit 44 and the like so as to discharge an SPM liquid to a wafer W (step S305).

Then, the controller 18 controls the SPM liquid supply unit 44, the water vapor supply unit 45, and the like so as to supply both an SPM liquid and a water vapor V to a nozzle 41a and thereby discharge a mixed fluid M to a wafer W (step S306).

Then, the controller 18 controls the water vapor supply unit 45 and the like so as to stop discharge of a water vapor V from the nozzle 41a (step S307) and subsequently controls the SPM liquid supply unit 44 and the like so as to stop discharge of an SPM liquid from the nozzle 41a (step S308).

Then, the controller 18 controls a hydrogen peroxide solution supply unit 49 and the like so as to discharge a hydrogen peroxide solution to a wafer W (step S309). Additionally, such a process at step S309 may be executed by scan-in-operating a nozzle 41c. Then, the controller 18 controls the rinsing liquid supply unit 46 and the like so as to execute a rinsing process for a wafer W by a rinsing liquid R that is a DIW (step S310).

Then, the controller 18 controls a processing unit 16 so as to execute a drying process (for example, spin drying) for a wafer W (step S311) and complete a series of substrate processing.

A substrate processing method according to an embodiment includes a processing liquid discharge step (step S105, S205, S305), and a mixed fluid discharge step (step S106, S206, S306). The processing liquid discharge step (step S105, S205, S305) discharges a processing liquid (an SPM liquid that is produced by mixing sulfuric acid and a hydrogen peroxide solution) to a substrate (a wafer W). The mixed fluid discharge step (step S106, S206, S306) discharges a mixed fluid M that is produced by mixing a processing liquid (an SPM liquid) and a purified water in a vapor state or a mist state thereof to the substrate (the wafer) where a processing liquid (an SPM liquid) is discharged. Thereby, it is possible to prevent or reduce contamination of a wafer W in a liquid process such as an SPM process.

Furthermore, the substrate processing method according to an embodiment further includes a liquid film formation step (step S102, S202, S302), and a purified water discharge step (step S5103, S203, S303). The liquid film formation step (step S5102, S5202, S302) discharges a rinsing liquid R to the substrate (the wafer W) to form a liquid film of a rinsing liquid R on a surface of the substrate (the wafer W). The purified water discharge step (step S103, S203, S303) discharges a purified water in a vapor state or a mist state thereof to a liquid film of a rinsing liquid R that is formed on a surface of the substrate (the wafer W). Then, the processing liquid discharge step (step S105, S205, S305) is executed after the purified water discharge step (step S103, S203, S303). Thereby, it is possible to prevent or reduce contamination of a wafer W that is caused by an impurity/impurities, a water scale, and/or the like.

Furthermore, in the substrate processing method according to an embodiment, the processing liquid discharge step (step S105, S205, S305) is executed for a surface of the substrate (the wafer W) where a liquid film of a rinsing liquid R is formed. Thereby, it is possible to prevent or reduce contamination of a wafer W that is caused by liquid splashing.

Furthermore, in the substrate processing method according to an embodiment, a rinsing liquid R is a hydrogen peroxide solution. Thereby, it is possible to execute a rinsing process for a wafer W efficiently.

Furthermore, the substrate processing method according to an embodiment further includes a hydrogen peroxide solution discharge step (step S309), and a rinsing step (step S310). The hydrogen peroxide solution discharge step (step S309) discharges a hydrogen peroxide solution to the substrate (the wafer W) after the mixed fluid discharge step (step S306). The rinsing step (step S310) discharges a rinsing liquid R that is a purified water to the substrate (the wafer W) after the hydrogen peroxide solution discharge step (step S309). Thereby, it is possible to further clean a surface of a wafer W where a liquid process such as an SPM process is applied.

Furthermore, in the substrate processing method according to an embodiment, the substrate (the wafer W) is rotated at a first rotational frequency at the processing liquid discharge step (step S105, S205, S305). Furthermore, the substrate (the wafer W) is rotated at a second rotational frequency that is less than the first rotational frequency at the mixed fluid discharge step (step S106, S206, S306). Thereby, it is possible to remove a resist film for a short processing time efficiently.

Furthermore, in the substrate processing method according to an embodiment, supply of a purified water in a vapor state or a mist state thereof is stopped prior to a processing liquid (an SPM liquid) when the mixed fluid discharge step (step S106, S206, S306) is ended. Thereby, it is possible to prevent or reduce contamination of a wafer W that is caused by an impurity/impurities, a water scale, and/or the like.

Furthermore, in the substrate processing method according to an embodiment, the mixed fluid M is produced by mixing a processing liquid (an SPM liquid) and a purified water in a vapor state or a mist state thereof after being discharged from a nozzle 41a and before reaching the substrate (the wafer W). Thereby, it is possible to supply a mixed fluid M at a high temperature to a wafer W.

Furthermore, in the substrate processing method according to an embodiment, the mixed fluid M is supplied to a center to a peripheral part of the substrate (the wafer W), and a rinsing liquid R is supplied in such a manner that a rinsing liquid R that is spread when contacting the substrate (the wafer W) covers a center of the substrate (the wafer W). Thereby, it is possible to execute a liquid process such as an SPM process efficiently.

Furthermore, the substrate processing method according to an embodiment further includes a rinsing step (S109, S209) that discharges a rinsing liquid to the substrate (the wafer W) after the mixed fluid discharge step (step S106, S206, S306). Furthermore, the rinsing step (S109, S209) first discharges a rinsing liquid toward a middle part Wm between a central part Wc and a peripheral part We of the substrate (the wafer W) and then gradually moves a discharge position for a rinsing liquid toward a central part Wc of the substrate (the wafer W). Thereby, it is possible to prevent or reduce causing of fluttering of a wafer W at an initial stage of a rinsing process.

Furthermore, in the substrate processing method according to an embodiment, the processing liquid is an SPM liquid that is produced by mixing sulfuric acid and a hydrogen peroxide solution. Thereby, it is possible to remove a resist film that is formed on a surface of a wafer W efficiently.

Although an embodiment of the present disclosure has been explained above, the present disclosure is not limited to an embodiment as described above and a variety of modifications are possible without departing from an essence thereof. For example, although an example where a rinsing process and a drying process are executed after an SPM process that is executed by a mixed fluid M has been illustrated in an embodiment as described above, a cleaning process or the like may be executed between the SPM process and the rinsing process. It is possible to execute such a cleaning process, for example, by discharging SC-1 (a mixed liquid of ammonia and a hydrogen peroxide solution) to a surface of a wafer W.

Furthermore, although an example where spin drying is executed as a drying process has been illustrated in an embodiment as described above, spin drying may be executed after discharging a drying liquid (for example, IPA (isopropyl alcohol)) to a surface of a wafer W.

According to the present disclosure, it is possible to prevent or reduce contamination of a substrate in a liquid process.

It should be considered that an embodiment(s) as disclosed herein is/are not limitative but is/are illustrative in all aspects thereof. In fact, it is possible to implement an embodiment(s) as described above in a variety of forms. Furthermore, an embodiment(s) as described above may be omitted, substituted, or modified in a variety of forms without departing from the appended claim(s) and an essence thereof.

What is claimed is:

1. A substrate processing method, comprising:
discharging a processing liquid to a substrate; and
discharging a mixed fluid that is produced by mixing the processing liquid and a purified water in a vapor state or a mist state thereof to the substrate where the processing liquid is discharged.

2. The substrate processing method according to claim 1, further comprising:
discharging a rinsing liquid to the substrate to form a liquid film of a rinsing liquid on a surface of the substrate; and
discharging a purified water in a vapor state or a mist state thereof to a liquid film of a rinsing liquid that is formed on a surface of the substrate, wherein
the discharging a processing liquid is executed after the discharging a purified water.

3. The substrate processing method according to claim 2, wherein
the discharging a processing liquid is executed for a surface of the substrate where a liquid film of a rinsing liquid is formed.

4. The substrate processing method according to claim 1, wherein
the rinsing liquid is a hydrogen peroxide solution.

5. The substrate processing method according to claim 1, further comprising:
discharging a hydrogen peroxide solution to the substrate after the discharging a mixed fluid; and
discharging a rinsing liquid that is a purified water to the substrate after the discharging a hydrogen peroxide solution.

6. The substrate processing method according to claim 1, wherein
the substrate is rotated at a first rotational frequency at the discharging a processing liquid, and
the substrate is rotated at a second rotational frequency that is less than the first rotational frequency at the discharging a mixed fluid.

7. The substrate processing method according to claim 1, wherein
supply of a purified water in a vapor state or a mist state thereof is stopped prior to the processing liquid when the discharging a mixed fluid is ended.

8. The substrate processing method according to claim 1, wherein
the mixed fluid is produced by mixing the processing liquid and a purified water in a vapor state or a mist state thereof after being discharged from a nozzle and before reaching the substrate.

9. The substrate processing method according to claim 1, wherein
the mixed fluid is supplied to a center to a peripheral part of the substrate, and
a rinsing liquid is supplied in such a manner that a rinsing liquid that is spread when contacting the substrate covers a center of the substrate.

10. The substrate processing method according to claim 1, further comprising
discharging a rinsing liquid to the substrate after the discharging a mixed fluid, wherein
the discharging a rinsing liquid includes first discharging a rinsing liquid toward a middle part between a central part and a peripheral part of the substrate and then gradually moving a discharge position for a rinsing liquid toward a central part of the substrate.

11. The substrate processing method according to claim 1, wherein
the processing liquid is an SPM liquid that is produced by mixing sulfuric acid and a hydrogen peroxide solution.

12. A substrate processing apparatus, comprising:
a holding unit that holds a substrate;
a liquid discharge unit that discharges a fluid to the substrate that is held by the holding unit;
a first supply unit that supplies a processing liquid to the liquid discharge unit;
a second supply unit that supplies a purified water in a vapor state or a mist state thereof to the liquid discharge unit; and
a controller that controls each unit, wherein
the controller discharges the processing liquid from the liquid discharge unit to the substrate that is held by the holding unit, and discharges a mixed fluid that is produced by mixing the processing liquid and a purified water in a vapor state or a mist state thereof, from the liquid discharge unit to the substrate where the processing liquid is discharged.
